(19) United States
(12) Patent Application Publication
(10) Pub. No.: US 2022/0320133 A1
(43) Pub. Date: Oct. 6, 2022

(54) METHOD FOR FORMING SEMICONDUCTOR STRUCTURE

(71) Applicant: YANGTZE MEMORY TECHNOLOGIES CO., LTD., Wuhan (CN)

(72) Inventors: Xiuzhong Liu, Wuhan (CN); Hao Zhang, Wuhan (CN); Haifeng Guo, Wuhan (CN)

(21) Appl. No.: 17/307,911

(22) Filed: May 4, 2021

Related U.S. Application Data
(63) Continuation of application No. PCT/CN2021/084516, filed on Mar. 31, 2021.

(51) Int. Cl. H01L 27/11582; H01L 21/02; H01L 27/11556

(52) U.S. Cl. CPC H01L 27/11582; H01L 21/02057; H01L 27/11556

(57) ABSTRACT

Methods for fabricating a semiconductor structure are disclosed. According to some aspects, a first layer is formed on a substrate, and an etch operation is performed to form an opening extending vertically through the first layer. A thermal treatment is performed on the substrate to remove a residual that residues in the opening when forming the opening. At least an oxygen gas is provided in the thermal treatment to react with the residual at a treatment temperature between 800° C. and 1,300° C.

### CROSS-REFERENCE TO RELATED APPLICATIONS

This application is continuation of International Application No. PCT/CN2021/084516, filed on Mar. 31, 2021, entitled “METHOD FOR FORMING SEMICONDUCTOR STRUCTURE,” which is hereby incorporated by reference in its entirety.

### BACKGROUND

The present disclosure relates to methods for forming three-dimensional (3D) semiconductor structures, and more particularly, to methods for forming 3D memory devices.

Planar semiconductor devices, such as memory cells, are scaled to smaller sizes by improving process technology, circuit design, programming algorithm, and fabrication process. However, as feature sizes of the semiconductor devices approach a lower limit, planar process and fabrication techniques become challenging and costly. A 3D semiconductor device architecture can address the density limitation in some planar semiconductor devices, for example, Flash memory devices.

A 3D semiconductor device can be formed by stacking semiconductor wafers or dies and interconnecting them vertically so that the resulting structure acts as a single device to achieve performance improvements at reduced power and a smaller footprint than conventional planar processes. Among the various techniques for stacking semiconductor substrates, bonding, such as hybrid bonding, is recognized as one of the promising techniques because of its capability of forming high-density interconnects.

### SUMMARY

Methods for forming 3D semiconductor structures are disclosed herein.

In one aspect, a method for forming a semiconductor structure is disclosed. A first layer is formed on a substrate, and an opening is formed extending vertically through the first layer. A thermal treatment is performed to the opening to remove a residual that residues in the opening when forming the opening. At least an oxygen gas is provided in the thermal treatment to react with the residual in the opening to form a gaseous compound of silicon and oxygen.

In another aspect, a method for forming a semiconductor structure is disclosed. A first layer is formed on a substrate, and an etch operation is performed to form an opening extending vertically through the first layer. A thermal treatment is performed to the opening to remove a residual that residues in the opening when forming the opening. At least an oxygen gas is provided in the thermal treatment to react with the residual at a treatment temperature between 800° C. and 1,300° C.

In still another aspect, a method for forming a three-dimensional (3D) memory device is disclosed. A stack structure is formed on a substrate, and the stack structure includes a plurality of interleaved first stack layers and second stack layers. An opening is formed extending vertically through the stack structure. A thermal treatment is performed to transform a residual that residues in the opening when forming the opening to a gaseous compound. The residual comprises at least one of silicon atoms or a compound of silicon and oxygen. A channel structure is formed in the opening.

In yet another aspect, a semiconductor manufacturing device is disclosed. The semiconductor manufacturing device includes a reaction chamber, and a substrate holder located in the reaction chamber to hold a substrate. A process temperature in the reaction chamber is between 800° C. and 1,300° C., and the reaction chamber is configured to perform a thermal treatment on the substrate to transform a residual on the substrate to a gaseous compound.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1 illustrates a scanning electron microscope image showing a cross-section of an exemplary 3D semiconductor device at a fabrication stage of a manufacturing process, according to some aspects of the present disclosure.

FIG. 2 illustrates a cross-section of an exemplary 3D memory device, according to some aspects of the present disclosure.

FIGS. 3A-3F illustrate cross-sections of an exemplary 3D memory device at different stages of a manufacturing process, according to some aspects of the present disclosure.

FIG. 4 illustrates a flowchart of an exemplary method for forming a 3D memory device, according to some aspects of the present disclosure.

FIG. 5 illustrates a sublimation variates schematic diagram for performing an exemplary method for forming a 3D memory device, according to some aspects of the present disclosure.

FIG. 6 illustrates a scanning electron microscope image showing a cross-section of an exemplary 3D semiconductor device at a fabrication stage of a manufacturing process, according to some aspects of the present disclosure.

FIG. 7 illustrates a flowchart of an exemplary method for forming a 3D memory device, according to some aspects of the present disclosure.

FIG. 8 illustrates a flowchart of an exemplary method for forming a 3D memory device, according to some aspects of the present disclosure.

FIG. 9 illustrates an exemplary semiconductor manufacturing device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

In some 3D memory devices, such as 3D NAND memory devices, a channel hole is typically formed before forming a channel structure. After forming the channel hole, one or several processes are usually used to clean the channel hole, including the sidewall and the bottom of the channel hole. The result of this cleaning has a great impact on the subsequent process. For example, when some residuals are not removed completely by the cleaning process, the residuals will affect the formation of the semiconductor plug of the channel structure.

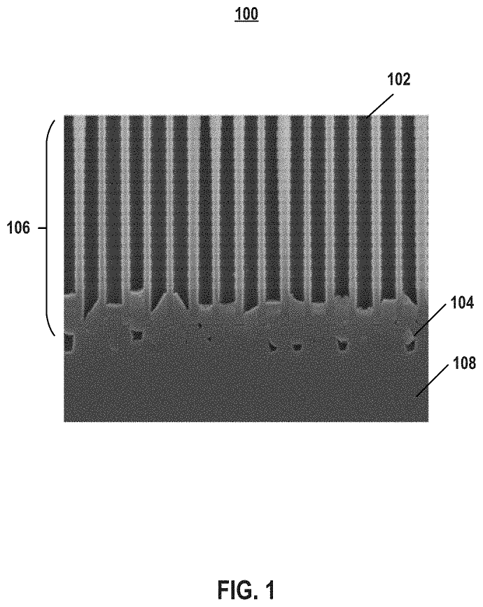

FIG. 1 illustrates a scanning electron microscope image 100 showing a cross-section of an exemplary channel hole 102 in a 3D memory device at a fabrication stage. As shown in FIG. 1, channel hole 102 extends vertically through a dielectric stack 106. Dielectric stack 106 may include a plurality of pairs, each including a first dielectric layer and a second dielectric layer formed above a substrate 108. An opening is etched through dielectric stack 106 and extends into part of substrate 108 to form channel hole 102, in which a NAND memory string can be formed. Channel hole 102 is usually formed by dry etching processes, such as deep reactive ion etching (DRIE). Some post-etch residuals (not shown) may remain in channel hole 102 before or even after the cleaning processes, such as wafer debris and polymers from a dry etching process. Generally, the post-etch residuals may include several compounds of silicon and oxygen, such as Si, SiO₂, or SiO. The residuals will affect the formation of the semiconductor plug 104.

Various implementations in accordance with the present disclosure provide an effective method for removing the post-etch residuals in channel hole 102 after the etch processes, and therefore improve the profile of the channel structure formed subsequently. Furthermore, the conventional process to remove the post-etch residuals uses low pressure anneal (LPA) process having long-term baking, and the process spends hours to have the post-etch residuals react with hydrogen. Since the conventional LPA cleaning process takes a long process time that generates much heat, the accumulated heat may cause metal internal stress and damage the semiconductor structure. The implementations in accordance with the present disclosure provide a quick and economical approach to remove the post-etch residuals.

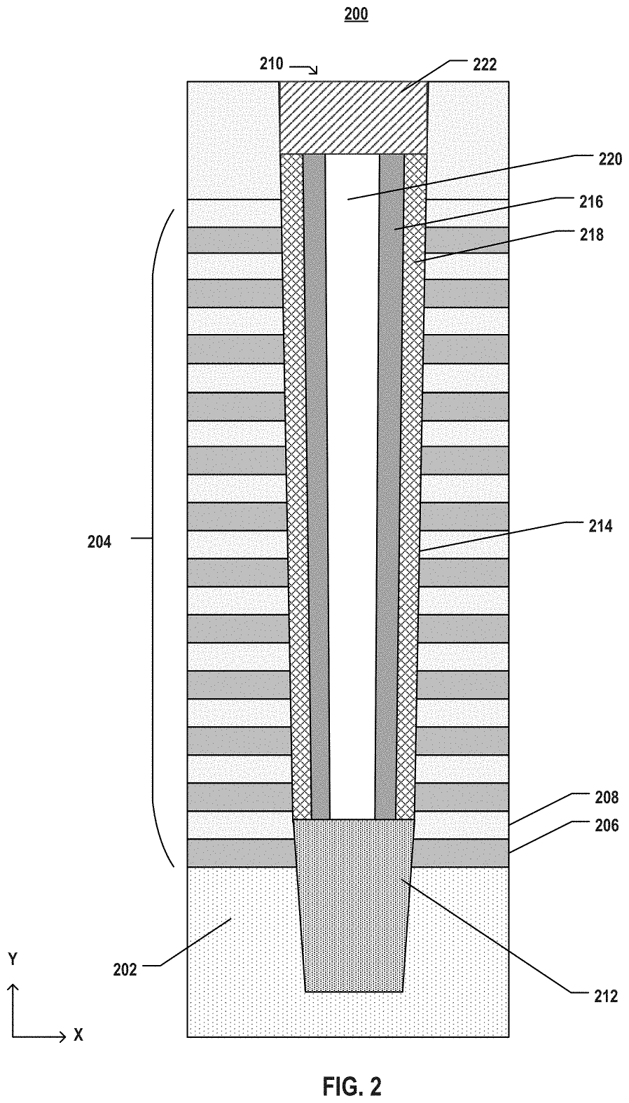

FIG. 2 illustrates a cross-section of an exemplary 3D memory device 200, according to some aspects of the present disclosure. 3D memory device 200 can include a substrate 202, which can include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 202 is a thinned substrate (e.g., a semiconductor layer), which was thinned by grinding, etching, chemical mechanical polishing (CMP), or any combination thereof. It is noted that x and y axes are included in FIG. 2 to further illustrate the spatial relationship of the components in 3D memory device 200. Substrate 202 of 3D memory device 200 includes two lateral surfaces (e.g., a top surface and a bottom surface) extending laterally in the x-direction (i.e., the lateral direction). As used herein, whether one component (e.g., a layer or a device) is “on,” “above,” or “below” another component (e.g., a layer or a device) of a 3D memory device (e.g., 3D memory device 200) is determined relative to the substrate of the 3D memory device (e.g., substrate 202) in they-direction (i.e., the vertical direction) when the substrate is positioned in the lowest plane of the 3D memory device in the y-direction. The same notion for describing spatial relationships is applied throughout the present disclosure.

3D memory device 200 can be part of a monolithic 3D memory device. The term “monolithic” means that the components (e.g., the peripheral device and memory array device) of the 3D memory device are formed on a single substrate. For monolithic 3D memory devices, the fabrication encounters additional restrictions due to the convolution of the peripheral device processing and the memory array device processing. For example, the fabrication of the memory array device (e.g., NAND memory strings) is constrained by the thermal budget associated with the peripheral devices that have been formed or to be formed on the same substrate.

Alternatively, 3D memory device 200 can be part of a non-monolithic 3D memory device, in which components (e.g., the peripheral device and memory array device) can be formed separately on different substrates and then bonded, for example, in a face-to-face manner. In some implementations, the memory array device substrate (e.g., substrate 202) remains as the substrate of the bonded non-monolithic 3D memory device, and the peripheral device (e.g., including any suitable digital, analog, and/or mixed-signal peripheral circuits used for facilitating the operation of 3D memory device 200, such as page buffers, decoders, and latches; not shown) is flipped and faces down toward the memory array device (e.g., NAND memory strings) for hybrid bonding. It is understood that in some implementations, the memory array device substrate (e.g., substrate 202) is flipped and faces down toward the peripheral device (not shown) for hybrid bonding, so that in the bonded non-monolithic 3D memory device, the memory array device is above the peripheral device. The memory array device substrate (e.g., substrate 202) can be a thinned substrate (which is not the substrate of the bonded non-monolithic 3D memory device), and the back-end-of-line (BEOL) interconnects of the non-monolithic 3D memory device can be formed on the backside of the thinned memory array device substrate.

In some implementations, 3D memory device 200 is a NAND Flash memory device in which memory cells are provided in the form of an array of NAND memory strings 210 each extending vertically above substrate 202. The memory array device can include NAND memory strings 210 that extend through a plurality of pairs each including a conductive layer 206 and a dielectric layer 208 (referred to herein as “conductive/dielectric layer pairs”). The stacked conductive/dielectric layer pairs are also referred to herein as a “memory stack” 204. In some implementations, a pad oxide layer (not shown) is formed between substrate 202 and memory stack 204. The number of the conductive/dielectric layer pairs in memory stack 204 determines the number of memory cells in 3D memory device 200. Memory stack 204 can include interleaved conductive layers 206 and dielectric layers 208. Conductive layers 206 and dielectric layers 208 in memory stack 204 can alternate in the vertical direction. Conductive layers 206 can include conductive materials including, but not limited to, tungsten (W), cobalt (Co), copper (Cu), aluminum (Al), polysilicon, doped silicon, silicides, or any combination thereof. Dielectric layers 208 can include dielectric materials including, but not limited to, silicon oxide, silicon nitride, silicon oxynitride, or any combination thereof.

As shown in FIG. 2, NAND memory string 210 can include a channel structure 214 extending vertically through memory stack 204. Channel structure 214 can include a channel hole filled with semiconductor materials (e.g., as a semiconductor channel 216) and dielectric materials (e.g., as a memory film 218). In some implementations, semiconductor channel 216 includes silicon, such as amorphous silicon, polysilicon, or single crystalline silicon. In some implementations, memory film 218 is a composite layer including a tunneling layer, a storage layer (also known as a “charge trap layer”), and a blocking layer. The remaining space of channel structure 214 can be partially or fully filled with a filling layer 220 including dielectric materials, such as silicon oxide. Channel structure 214 can have a cylinder shape (e.g., a pillar shape). Filling layer 220, semiconductor channel 216, the tunneling layer, the storage layer, and the blocking layer are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high dielectric constant (high-k) dielectrics, or any combination thereof. In one example, memory film 218 can include a composite layer of silicon oxide/silicon oxynitride (or silicon nitride)/silicon oxide (ONO).

In some implementations, conductive layer 206 (each being a word line or part of a word line) in memory stack 204 functions as a gate conductor of memory cells in NAND memory string 210. Conductive layer 206 can extend laterally as a word line coupling a plurality of memory cells. In some implementations, memory cell transistors in NAND memory string 210 include semiconductor channel 216, memory film 218, gate conductors (i.e., parts of conductive layers 206 that abut channel structure 214) made from tungsten, adhesion layers (not shown) including titanium/titanium nitride (Ti/TiN) or tantalum/tantalum nitride (Ta/TaN), gate dielectric layers (not shown) made from high-k dielectric materials, and channel structure 214 including polysilicon.

In some implementations, NAND memory string 210 further includes a semiconductor plug 212 in a lower portion (e.g., at the lower end) of NAND memory string 210 below channel structure 214. As used herein, the “upper end” of a component (e.g., NAND memory string 210) is the end farther away from substrate 202 in the y-direction, and the “lower end” of the component (e.g., NAND memory string 210) is the end closer to substrate 202 in the y-direction when substrate 202 is positioned in the lowest plane of 3D memory device 200. Semiconductor plug 212 can include a semiconductor material, such as silicon, which is epitaxially grown from substrate 202 in any suitable directions. It is understood that in some implementations, semiconductor plug 212 includes single crystalline silicon, the same material as substrate 202. In other words, semiconductor plug 212 can include an epitaxially-grown semiconductor layer that is the same as the material of substrate 202. In some implementations, part of semiconductor plug 212 is above the top surface of substrate 202 and in contact with semiconductor channel 216. Semiconductor plug 212 can function as a channel controlled by a source select gate of NAND memory string 210. It is understood that in some implementations, 3D memory device 200 does not include semiconductor plug 212.

In some implementations, NAND memory string 210 further includes a channel plug 222 in an upper portion (e.g., at the upper end) of NAND memory string 210. Channel plug 222 can be in contact with the upper end of semiconductor channel 216. Channel plug 222 can include semiconductor materials (e.g., polysilicon). By covering the upper end of channel structure 214 during the fabrication of 3D memory device 200, channel plug 222 can function as an etch stop layer to prevent etching of dielectrics filled in channel structure 214, such as silicon oxide and silicon nitride. In some implementations, channel plug 222 also functions as the drain of NAND memory string 210. It is understood that in some implementations, 3D memory device 200 does not include channel plug 222.

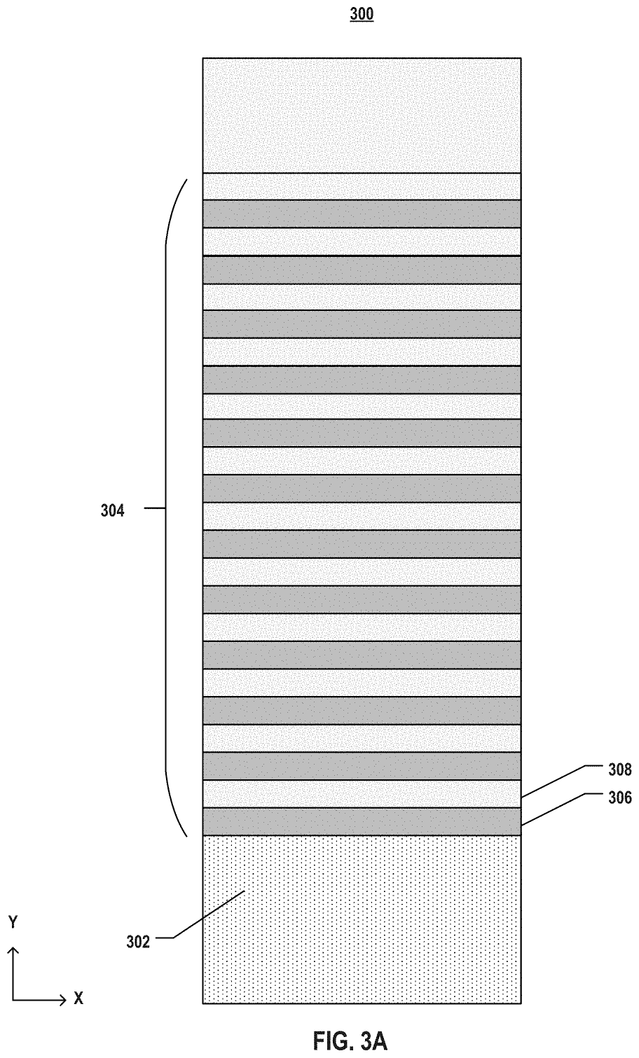

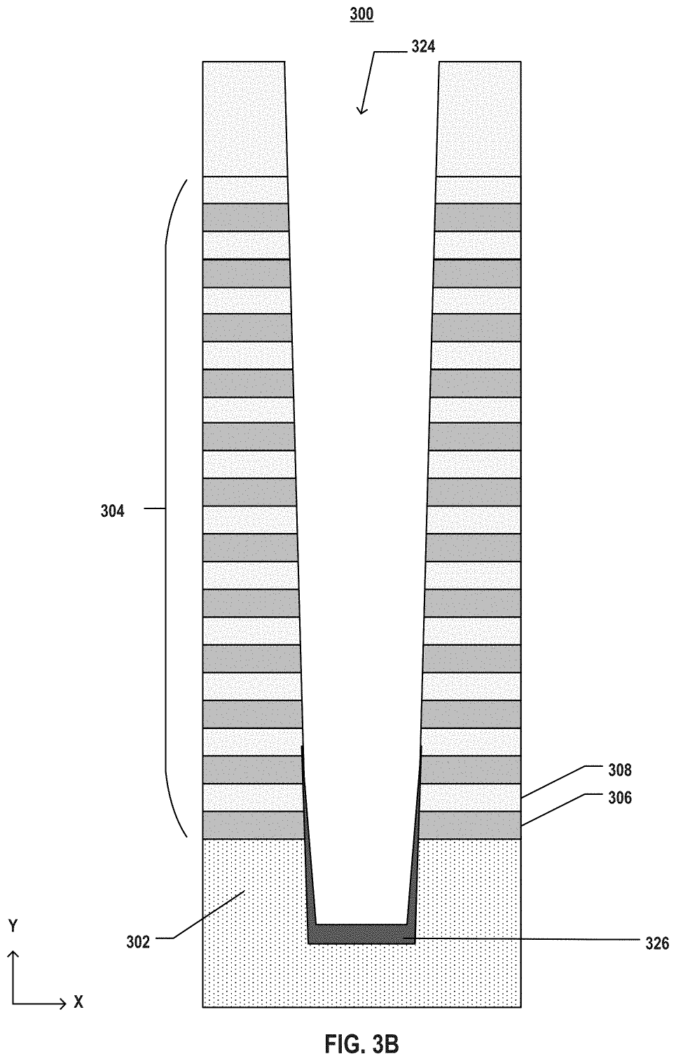

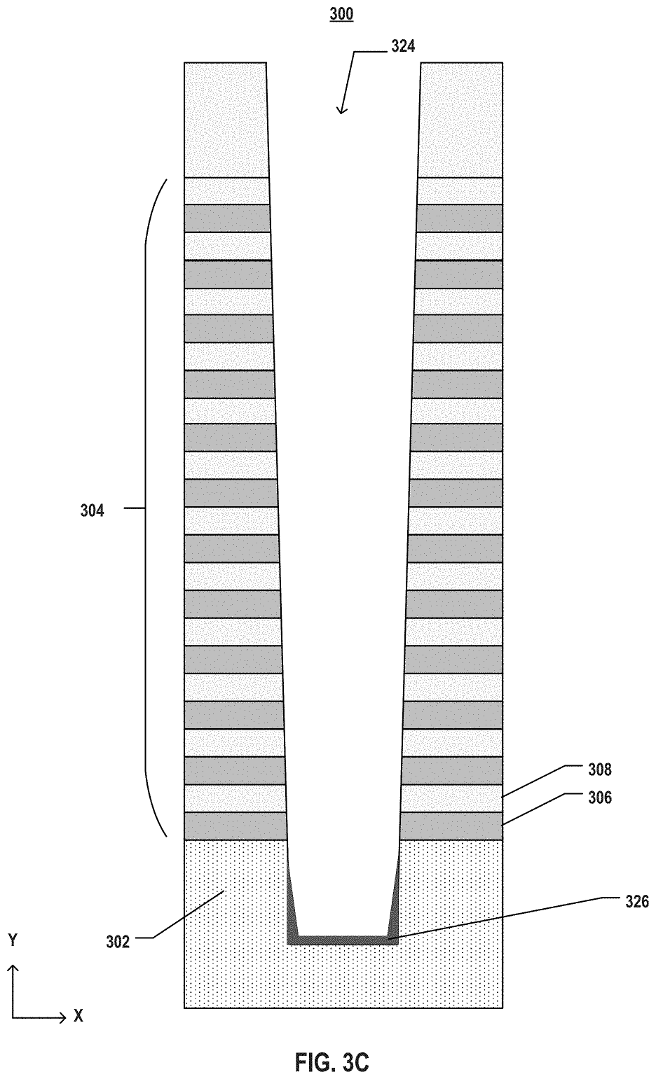

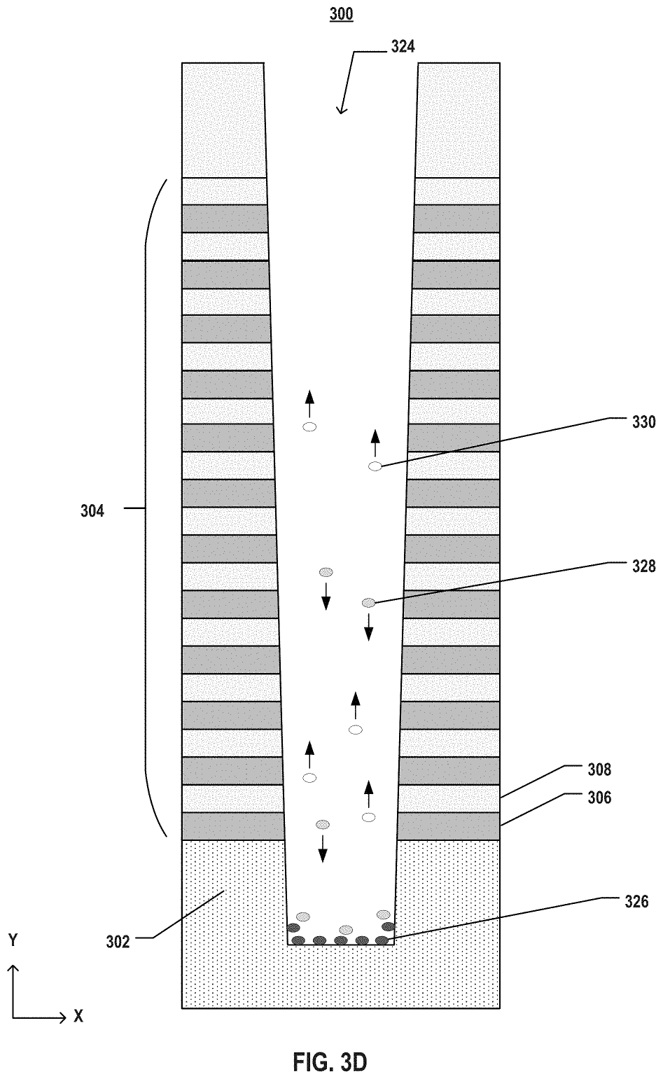

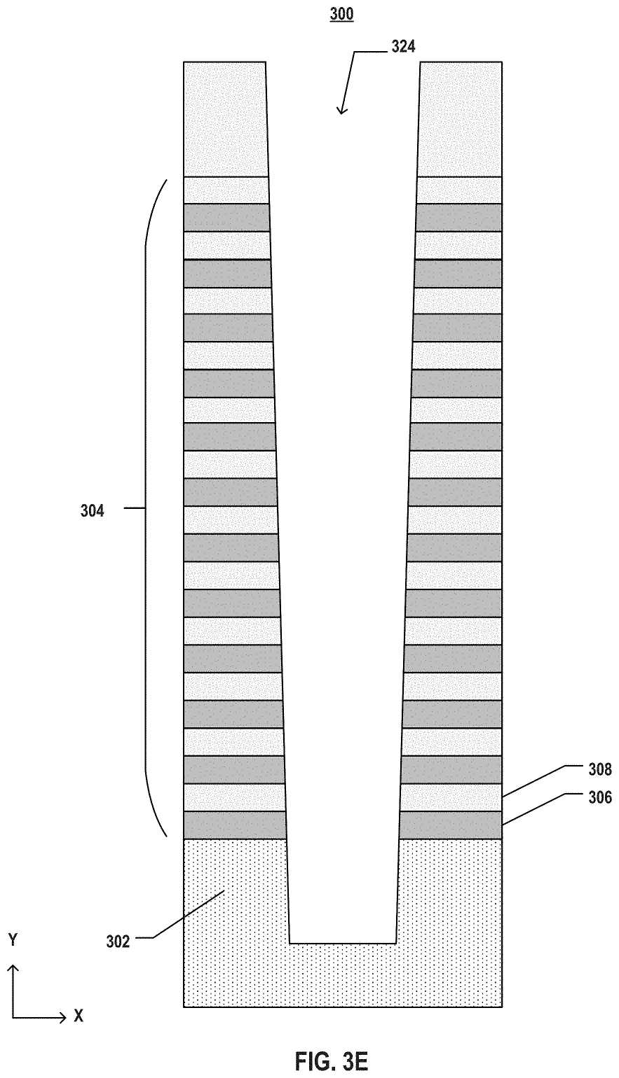

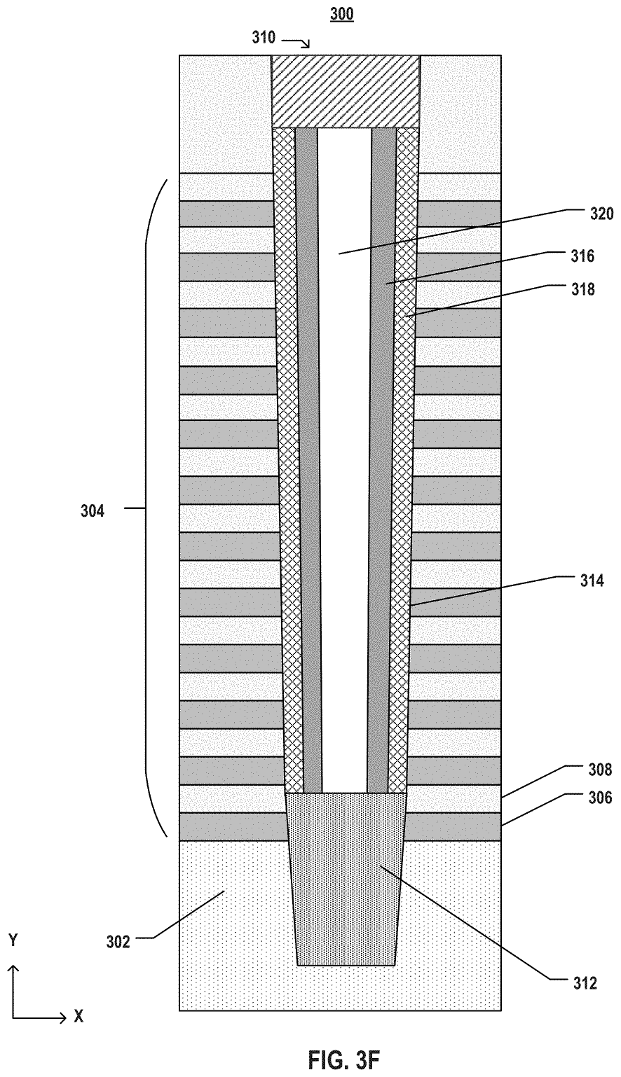

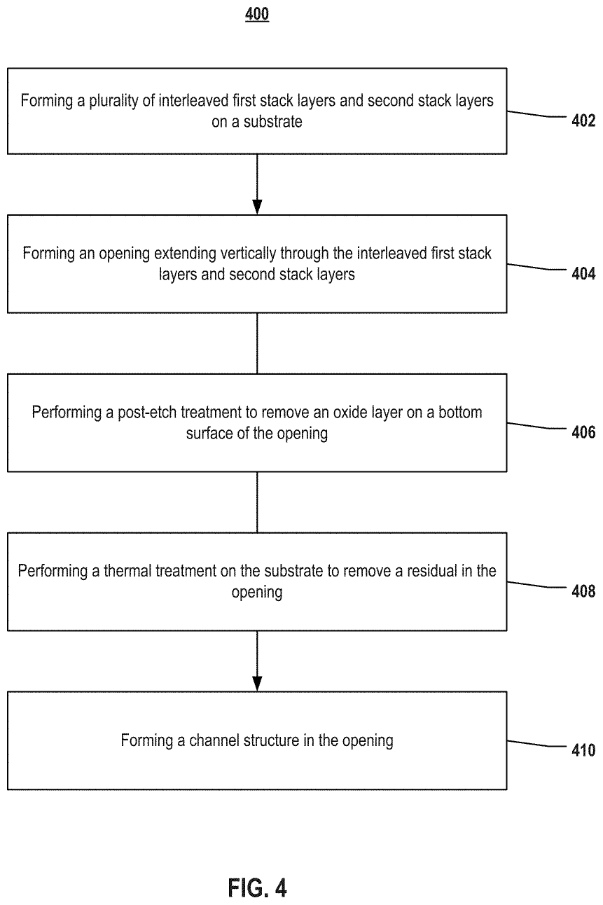

FIGS. 3A-3F illustrate cross-sections of an exemplary 3D memory device 300 at different stages of a manufacturing process, according to some aspects of the present disclosure. FIG. 4 illustrates a flowchart of an exemplary method 400 for forming a 3D memory device, according to some aspects of the present disclosure. For the purpose of better explaining the present disclosure, the cross-sections of 3D memory device 300 in FIGS. 3A-3F and method 400 in FIG. 4 will be described together. It is understood that the operations shown in method 400 are not exhaustive and that other operations can be performed as well before, after, or between any of the illustrated operations. Further, some of the operations may be performed simultaneously, or in a different order than shown in FIGS. 3A-3F and FIG. 4.

As shown in FIG. 3A and operation 402 of FIG. 4, a stack structure 304 is formed on a substrate 302. Stack structure 304 includes a plurality of interleaved first stack layers 308 and second stack layers 306. Substrate 302 may be a silicon substrate and first stack layers 308 and second stack layers 306 may be alternatively deposited on substrate 302 to form stack structure 304. In some implementations, stack structure 304 is a dielectric stack, each first stack layer 308 is a first dielectric layer, and each second stack layer 306 is a second dielectric layer different from the first dielectric layer (a.k.a. sacrificial layer). In some implementations, each first stack layer 308 may include a layer of silicon oxide, and each second stack layer 306 may include a layer of silicon nitride. Stack structure 304 may be formed by one or more thin film deposition processes including, but not limited to, chemical vapor deposition (CVD), physical vapor deposition (PVD), atomic layer deposition (ALD), or any combination thereof. In some implementations, a pad oxide layer (not shown) is formed between substrate 302 and stack structure 304 by depositing dielectric materials, such as silicon oxide, on substrate 302.

As shown in FIG. 3B and operation 404 of FIG. 4, an opening 324 is formed in stack structure 304. Opening 324 extends vertically through the interleaved first stack layers 308 and second stack layers 306. Opening 324 is etched through interleaved first stack layers 308 and second stack layers 306 and forms a channel hole for a channel structure of 3D memory device 300. In some implementations, a plurality of openings are formed through stack structure 304 such that each opening becomes the location for growing an individual NAND memory string in the later process. In some implementations, fabrication processes for forming opening 324 may include wet etching and/or dry etching, such as DRIE. In some implementations, opening 324 may extend further into the top portion of substrate 302.

The etching process through stack structure 304 may not stop at the top surface of substrate 302 and may continue to etch part of substrate 302. In some implementations, a separate etching process is used to etch part of substrate 302 after etching through stack structure 304. After etching, the residuals 326 may remain in opening 324, for example, on the sidewall and/or bottom surface of opening 324. In some implementations, residuals 326 may include native oxide formed in the lower portion of opening 324, for example, on the sidewall and bottom surface where substrate 302 is exposed in the air. In some implementations, residuals 326 may also include post-etch residuals from the drying etching process in forming opening 324, such as wafer debris and polymers, remaining in opening 324, for example, on the sidewall and/or bottom surface of opening 324.

As shown in FIG. 3C and operation 406 of FIG. 4, a post-etch treatment is performed to remove residuals 326 formed in the lower portion of opening 324. Operation 406 may be performed by wet etching and/or dry etching. In some implementations, an etchant is applied through opening 324 to remove residuals 326 in opening 324. As shown in FIG. 3C, after operation 406, a portion of residuals 326 in opening 324 is removed, and another portion of residuals 326 is still remained on the sidewall and/or bottom surface of opening 324. Residuals 326 after the post-etch treatment may include oxygen atoms, silicon atoms, or a compound of silicon and oxygen, for example, SiO or SiO₂.

As shown in FIG. 3D and operation 408 of FIG. 4, a thermal treatment is performed to remove residual 326 in opening 324. The oxygen gas 328 is provided in operation 408 to react with residuals 326. Residuals 326 include oxygen atoms, silicon atoms or a compound of silicon and oxygen, and oxygen gas 328 and residual 326 may react and form a compound of silicon and oxygen, for example, silicon monoxide. In some implementations, by controlling the process temperature and the oxygen concentration, the compound of silicon and oxygen may be transformed to a gaseous compound of silicon and oxygen, for example, gaseous silicon monoxide. The gaseous compound is easy to be removed from the bottom of opening 324. As shown in FIG. 3D, oxygen gas 328 is provided in opening 324 to react with residuals 326 on the sidewall or bottom of opening 324 to form gaseous compound 330. Gaseous compound 330 is removed from opening 324.

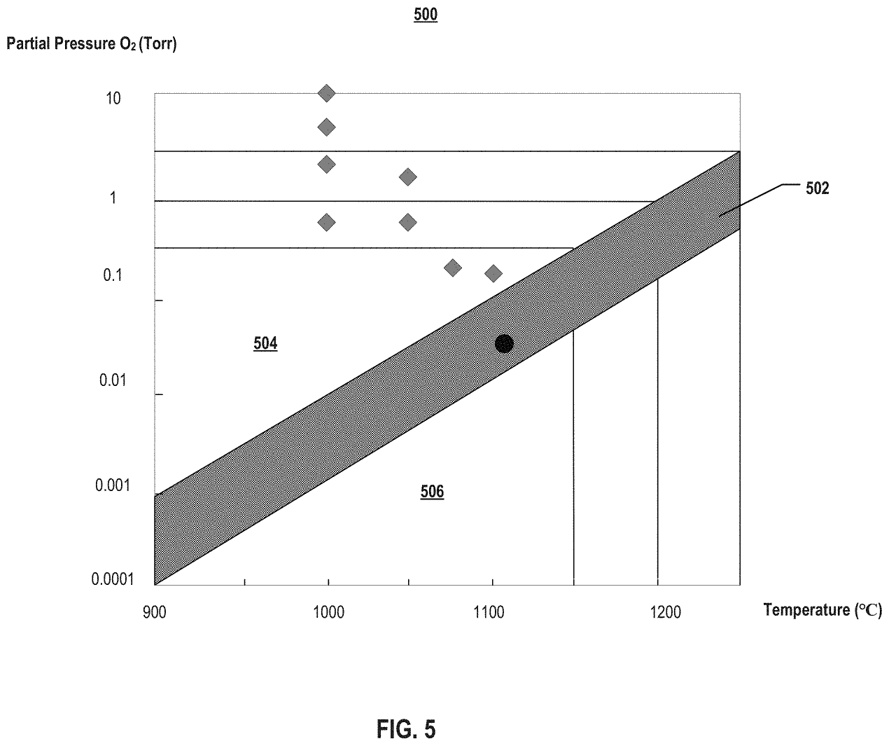

FIG. 5 illustrates a sublimation variates schematic diagram 500 for performing method 400 for forming a 3D memory device, according to some aspects of the present disclosure. As shown in FIG. 5, the process condition that impacts the sublimation of gaseous compound 330 may include the process temperature and the oxygen partial pressure. When the process temperature and the oxygen partial pressure are controlled in sublimation area 502, residuals 326 may react with oxygen gas 328 to form and transform to gaseous compound of silicon and oxygen, for example, gaseous silicon monoxide. When the process temperature and the oxygen partial pressure are controlled in area 504, residuals 326 may react with oxygen gas 328 to form silicon dioxide. When the process temperature and the oxygen partial pressure are controlled in area 506, residuals 326 may react with oxygen gas 328 to form a solid silicon monoxide.

During the thermal treatment, in some implementations, the process temperature of the thermal treatment may be controlled above 900° C. In some implementations, the process temperature of the thermal treatment may be controlled between 800° C. and 1,300° C. In some implementations, the process temperature of the thermal treatment may be controlled between 850° C. and 1,250° C. In some implementations, the process temperature may be controlled between 900° C. and 1,200° C.

The oxygen partial pressure in a reaction chamber is affected by the oxygen flow and the process temperature. When the oxygen flow and the process temperature are changed, the oxygen partial pressure is changed accordingly as well. In some implementations, the oxygen partial pressure in the thermal treatment is controlled between 0.0001 Torr and 10 Torrs. In some implementations, the oxygen partial pressure in the thermal treatment is controlled between 0.0001 Torr and 5 Torrs. In some implementations, the oxygen partial pressure in the thermal treatment is controlled between 0.0001 Torr and 1 Torr. In some implementations, the process time of the thermal treatment may be less than 10 minutes. In some implementations, the process time of the thermal treatment may be less than 5 minutes. In some implementations, the process time of the thermal treatment may be less than 3 minutes.

FIG. 3E shows the result of the thermal treatment. As shown in FIG. 3E, after the thermal treatment, residuals 326 are removed from the lower portion of opening 324, including the sidewall and bottom surface. The thermal treatment used to remove residuals 326 has the characteristics of short process time, so that the heat accumulated in the operation would be reduced and the metal internal stress would not be affected, and the fabrication cost would also be lowered. Therefore, the LPA process is not required in the present disclosure, and the LPA cleaning process can be replaced by the thermal treatment of operation 408 to achieve an improved opening profile. Furthermore, residuals 326 are transformed to gaseous compound 330 in the thermal treatment and gaseous compound 330 is easy to remove in the reaction chamber, so that the cleaning effect of the disclosed method is better than the conventional methods.

Optionally, after operation 408, an etch process may be performed in opening 324 to selectively remove a portion of first stack layers 308 and second stack layers 306. In some implementations, first stack layers 308 and second stack layers 306 are silicon oxide layers and silicon nitride layers, and an etchant with high selectivity to silicon nitride and silicon oxide may be provided to further clean opening 324. The etchant with a selectivity ranging from 1 to 50 (silicon nitride to silicon oxide) is applied through opening 324. In some embodiments, the selectivity can be between 1 to 50 (e.g., 1, 2, 3, 4, 5, 6, 7, 8, 9, 10, 15, 20, 25, 30, 35, 40, 45, 50, any range bounded by the lower end by any of these values, or in any range defined by any two of these values). Shallow recesses are formed by etching parts of the silicon nitride layer abutting the sidewall of the opening.

In some implementations, an epitaxial operation, e.g., a selective epitaxial growth operation, may be performed to form a semiconductor layer on the bottom of opening 324. Because the thermal treatment removes residuals 326 from the lower portion of opening 324, the semiconductor layer formed on the bottom of opening 324 may have a better growth.

As shown in FIG. 3F and operation 410 of FIG. 4, after the thermal treatment, a NAND memory string 310 is formed in opening 324. NAND memory string 310 extends vertically through stack structure 304 above substrate 302. NAND memory string 310 may include a channel structure 314 extending vertically through stack structure 304. Channel structure 314 may include a semiconductor channel 316, a memory film 318, and a capping layer 320. Channel structure 314 may have a cylinder shape (e.g., a pillar shape). In some implementations, NAND memory string 310 further includes a semiconductor plug 312 in a lower portion (e.g., at the lower end) of NAND memory string 310 below channel structure 314. Semiconductor plug 312 can include a semiconductor material, such as silicon, which is epitaxially grown from substrate 302 in any suitable direction. Because the thermal treatment removes residuals 326 from the lower portion of opening 324, the growth of semiconductor plug 312 may have a better profile.

It is understood that, in FIGS. 3A-3F and FIG. 4, stack structure 304 including first stack layer 308 and second stack layer 306 is used as examples to explain the present disclosure, and first stack layer 308 and second stack layer 306 may have different structure or operation according to different process procedure. In some implementations, stack structure 304 is a dielectric stack, each first stack layer 308 is a first dielectric layer, and each second stack layer 306 is a second dielectric layer different from the first dielectric layer (a.k.a. sacrificial layer). The sacrificial layers could be removed and be replaced with conductive layers (e.g., W) in the consequential processes to form the gate layers (word lines of the 3D NAND memory device). In some implementations, each first stack layer 308 is a dielectric layer, and each second stack layer 306 is a conductive layer (e.g., polysilicon). The conductive layers could be the gate layers of the 3D NAND memory device, and the gate replacement process is not required.

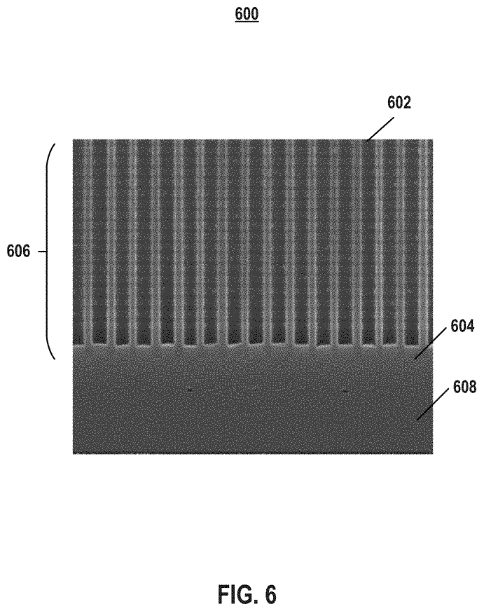

FIG. 6 illustrates a scanning electron microscope image 600 showing a cross-section of an exemplary 3D semiconductor device at a fabrication stage of a manufacturing process, according to some aspects of the present disclosure. In FIG. 6, a channel hole 602 extends vertically through a dielectric stack 606. Dielectric stack 606 may include a plurality of pairs, each including a first dielectric layer and a second dielectric layer formed above a substrate 608. After the thermal treatment, the residuals are removed, and the lower portion of channel hole 602 has a better clean result, and therefore the formation of the semiconductor plug 604 would have a better profile.

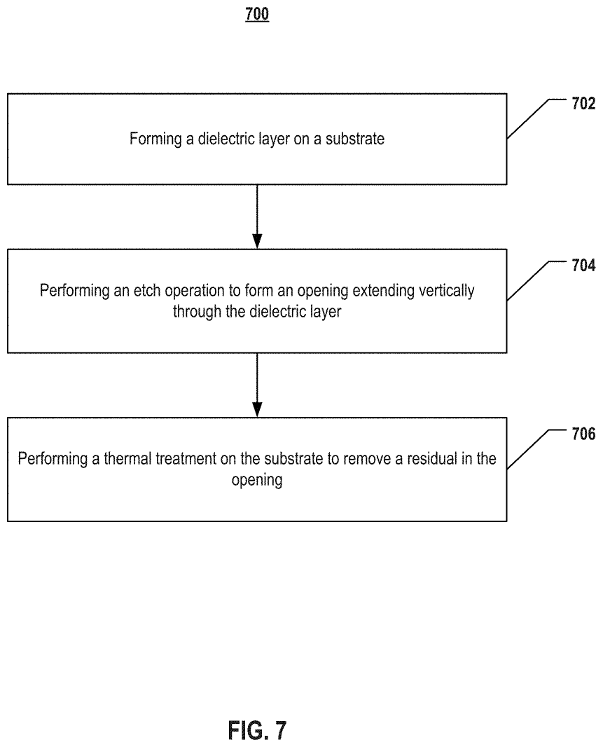

FIG. 7 illustrates a flowchart of an exemplary method 700 for forming a 3D memory device, according to some aspects of the present disclosure. In operation 702, a dielectric layer is formed on a substrate. The dielectric layer may be a dielectric stack including a plurality of interleaved first stack layers and second stack layers, for example, a plurality of interleaved silicon oxide and silicon nitride. The substrate may be a silicon substrate, and the first stack layers and the second stack layers may be alternatively deposited on the silicon substrate. The dielectric stack may be formed by one or more thin film deposition processes including, but not limited to, CVD, PVD, ALD, or any combination thereof.

In operation 704, an etch operation is performed to form an opening extending vertically through the dielectric layer. The opening is etched through the dielectric layer and forms a channel hole for a channel structure of 3D memory device. In some implementations, fabrication processes for forming the opening may include wet etching and/or dry etching, such as DRIE. In some implementations, the opening may extend further into the top portion of the substrate. After the etch process of forming the opening, the residuals may remain in the opening, for example, on the sidewall and/or bottom surface of the opening. In some implementations, the residuals may include native oxide formed in the lower portion of the opening, for example, on the sidewall and bottom surface where the substrate is exposed in the air. In some implementations, the residuals may also include post-etch residuals from the drying etching process in forming the opening, such as wafer debris and polymers, remaining in the opening, for example, on the sidewall and/or bottom surface of the opening.

In operation 706, a thermal treatment is performed on the substrate to remove the residuals in the opening. The oxygen gas is provided in operation 706 to react with the residuals. The residuals may include oxygen atoms, silicon atoms, or a compound of silicon and oxygen, and the oxygen gas and the residual may react and form a compound of silicon and oxygen, for example, silicon monoxide. In some implementations, by controlling the process temperature and the oxygen concentration, the compound of silicon and oxygen may be transformed to a gaseous compound of silicon and oxygen, for example, gaseous silicon monoxide. The gaseous compound is easy to be removed from the bottom of the opening.

During the thermal treatment, in some implementations, the process temperature of the thermal treatment may be controlled above 900° C. In some implementations, the process temperature of the thermal treatment may be controlled between 800° C. and 1,300° C. In some implementations, the process temperature of the thermal treatment may be controlled between 850° C. and 1,250° C. In some implementations, the process temperature may be controlled between 900° C. and 1,200° C.

In some implementations, the oxygen partial pressure in the thermal treatment is controlled between 0.0001 Torr and 10 Torrs. In some implementations, the oxygen partial pressure in the thermal treatment is controlled between 0.0001 Torr and 5 Torrs. In some implementations, the oxygen partial pressure in the thermal treatment is controlled between 0.0001 Torr and 1 Torr. In some implementations, the process time of the thermal treatment may be less than 10 minutes. In some implementations, the process time of the thermal treatment may be less than 5 minutes. In some implementations, the process time of the thermal treatment may be less than 3 minutes.

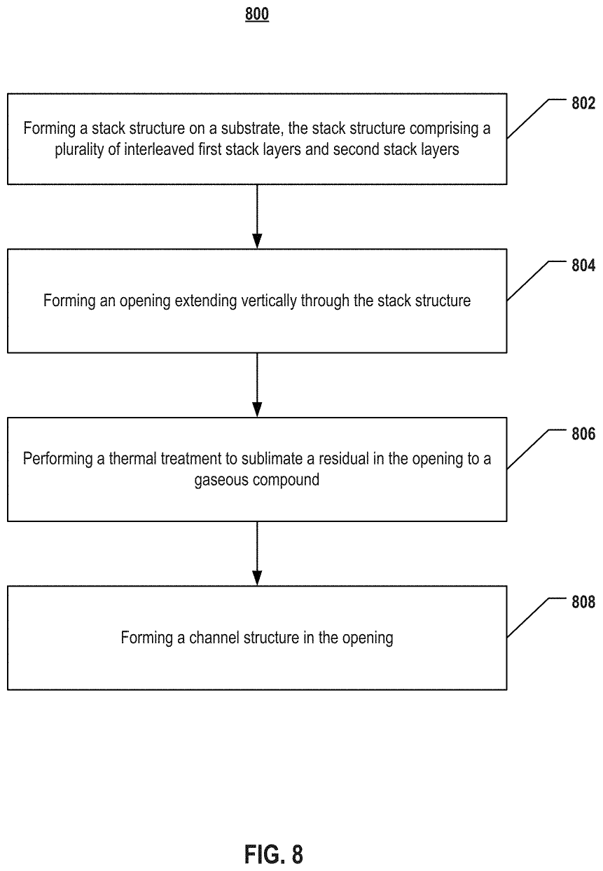

FIG. 8 illustrates a flowchart of an exemplary method 800 for forming a 3D memory device, according to some aspects of the present disclosure. In operation 802, a stack structure is formed on a substrate. The stack structure includes a plurality of interleaved first stack layers and second stack layers. The substrate may be a silicon substrate, and the first stack layers and the second stack layers may be alternatively deposited on the silicon substrate. The dielectric stack may be formed by one or more thin film deposition processes including, but not limited to, CVD, PVD, ALD, or any combination thereof.

In operation 804, an opening is formed extending vertically through the dielectric stack. The opening is etched through the dielectric stack and forms a channel hole for a channel structure of 3D memory device. In some implementations, fabrication processes for forming the opening may include wet etching and/or dry etching. In some implementations, the opening may extend further into the top portion of the substrate. After the etch process of forming the opening, the residuals may remain in the opening, for example, on the sidewall and/or bottom surface of the opening. In some implementations, the residuals may include native oxide formed in the lower portion of the opening, for example, on the sidewall and bottom surface where the substrate is exposed in the air. In some implementations, the residuals may also include post-etch residuals from the drying etching process in forming the opening, such as wafer debris and polymers, remaining in the opening, for example, on the sidewall and/or bottom surface of the opening.

In operation 806, a thermal treatment is performed to transform the residuals in the opening to a gaseous compound. The oxygen gas is provided in operation 806 to react with the residuals. The residuals may include oxygen atoms, silicon atoms, or a compound of silicon and oxygen, and the oxygen gas and the residual may react and form a compound of silicon and oxygen, for example, silicon monoxide. In some implementations, by controlling the process temperature and the oxygen concentration, the compound of silicon and oxygen may be transformed to a gaseous compound of silicon and oxygen, for example, gaseous silicon monoxide. The gaseous compound is easy to be removed from the bottom of the opening.

During the thermal treatment, in some implementations, the process temperature of the thermal treatment may be controlled above 900° C. In some implementations, the process temperature of the thermal treatment may be controlled between 800° C. and 1,300° C. In some implementations, the process temperature of the thermal treatment may be controlled between 850° C. and 1,250° C. In some implementations, the process temperature may be controlled between 900° C. and 1,200° C.

In some implementations, the oxygen partial pressure in the thermal treatment is controlled between 0.0001 Torr and 10 Torrs. In some implementations, the oxygen partial pressure in the thermal treatment is controlled between 0.0001 Torr and 5 Torrs. In some implementations, the oxygen partial pressure in the thermal treatment is controlled between 0.0001 Torr and 1 Torr. In some implementations, the process time of the thermal treatment may be less than 10 minutes. In some implementations, the process time of the thermal treatment may be less than 5 minutes. In some implementations, the process time of the thermal treatment may be less than 3 minutes.

In operation 808, a channel structure is formed in the opening. The channel structure extends vertically through the dielectric stack. The channel structure may include a semiconductor plug in a lower portion of the channel structure. The semiconductor plug may include a semiconductor material, such as silicon, which is epitaxially grown from the substrate in any suitable direction. Because the thermal treatment removes the residuals from the lower portion of the opening, the growth of the semiconductor plug may have a better profile.

The thermal treatment used to remove the residuals has the characteristics of high process temperature and short process time, so that the metal internal stress would not be affected, and the fabrication cost would also be lowered. Furthermore, the residuals are transformed to the gaseous compound in the thermal treatment, and the gaseous compound is easy to remove in the reaction chamber, so that the cleaning effect of the disclosed method is better than the conventional methods.

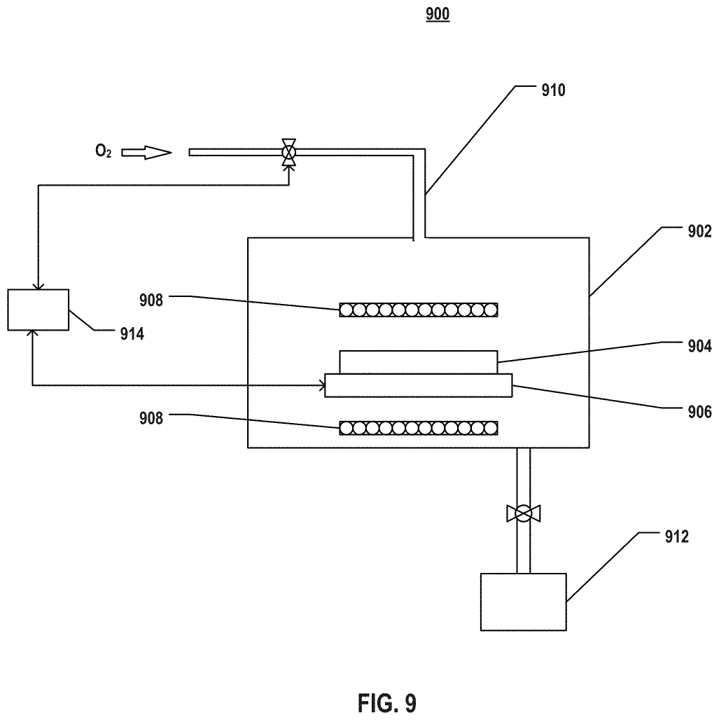

FIG. 9 illustrates an exemplary semiconductor manufacturing device 900, according to some aspects of the present disclosure. Semiconductor manufacturing device 900 includes a reaction chamber 902, a substrate holder 906 located in reaction chamber 902 to hold a substrate 904, a heater 908 in reaction chamber 902 to control a process temperature, a gas source connected to reaction chamber 902 through a gasline 910, and the gas source includes at least oxygen gas. In some implementations, reaction chamber 902 and the gas source are configured to perform a thermal treatment on substrate 904 to transform a residual on substrate 904 to a gaseous compound.

The residuals on the substrate may include silicon atoms, oxygen atoms, and a compound of silicon and oxygen. By performing the thermal treatment by semiconductor manufacturing device 900, the residuals on the substrate may be transformed to a gaseous compound of silicon and oxygen, for example, silicon monoxide.

In some implementations, heater 908 may control the process temperature of the thermal treatment. In some implementations, the process temperature of the thermal treatment may be controlled above 900° C. In some implementations, the process temperature of the thermal treatment may be controlled between 800° C. and 1,300° C. In some implementations, the process temperature of the thermal treatment may be controlled between 850° C. and 1,250° C. In some implementations, the process temperature may be controlled between 900° C. and 1,200° C.

In some implementations, semiconductor manufacturing device 900 may include an evacuation unit 912 to maintain the process pressure in reaction chamber 902. In some implementations, evacuation unit 912 may be a vacuum pump including a pressure control valve. The oxygen gas is supplied to reaction chamber 902 to react with the residuals. In some implementations, the oxygen partial pressure in the thermal treatment is controlled between 0.0001 Torr and 10 Torrs. In some implementations, the oxygen partial pressure in the thermal treatment is controlled between 0.0001 Torr and 5 Torrs. In some implementations, the oxygen partial pressure in the thermal treatment is controlled between 0.0001 Torr and 1 Torr. In some implementations, the process time of the thermal treatment may be less than 10 minutes. In some implementations, the process time of the thermal treatment may be less than 5 minutes. In some implementations, the process time of the thermal treatment may be less than 3 minutes.

In some implementations, semiconductor manufacturing device 900 may further include a controller 914. Controller 914 may control a heater temperature of heater 908 to keep the process temperature in reaction chamber 902 between 800° C. and 1,300° C. Controller 914 may also control the gas source to provide the oxygen gas to reaction chamber 902 during the thermal treatment. In some implementations, controller 914 cooperating with heater 908 and the gas source may constitute a chamber environment of reaction chamber 902 capable of sublimating the residual on substrate 904 to the gaseous compound.

When the process temperature and the oxygen partial pressure are controlled in sublimation area 502 as shown in FIG. 5, the residuals may react with the oxygen gas to form and transform to gaseous compound of silicon and oxygen, for example, gaseous silicon monoxide. The gaseous compound is easy to remove from the substrate in the reaction chamber, so that the cleaning effect of semiconductor manufacturing device 900 is better than the conventional devices.

According to one aspect of the present disclosure, a method for forming a semiconductor structure is disclosed. A first layer is formed on a substrate. An opening is formed extending vertically through the first layer. A thermal treatment is performed to the opening to remove a residual that residues in the opening when forming the opening. At least an oxygen gas is provided to react with the residual in the opening to form a gaseous compound of silicon and oxygen.

In some implementations, a channel structure is formed in the opening. In some implementations, a selective epitaxial growth operation is performed to form a second layer on a bottom of the opening. In some implementations, the thermal treatment is performed at a treatment temperature between 800° C. and 1,300° C. In some implementations, the thermal treatment is performed within a treatment time of less than 10 minutes. In some implementations, the oxygen gas is provided having a partial pressure between 0.0001 Torr and 10 Torrs.

In some implementations, the residual includes at least one of silicon atoms or a compound of silicon and oxygen. In some implementations, at least the oxygen gas is provided to react with at least one of the silicon atoms or the compound of silicon and oxygen to form the gaseous compound of silicon and oxygen. In some implementations, the gaseous compound of silicon and oxygen is silicon monoxide.

In some implementations, a post-etch treatment is performed to remove an oxide layer on a bottom surface of the opening. In some implementations, the semiconductor layer includes a stack structure having a plurality of interleaved first stack layers and second stack layers.

According to another aspect of the present disclosure, a method for forming a semiconductor structure is disclosed. A first layer is formed on a substrate. An etch operation is performed to form an opening extending vertically through the first layer. A thermal treatment is performed to the opening to remove a residual that residues in the opening when forming the opening. At least an oxygen gas is provided to react with the residual at a treatment temperature between 800° C. and 1,300° C.

In some implementations, the thermal treatment is performed within a treatment time of less than 10 minutes. In some implementations, the oxygen gas is provided having a partial pressure between 0.0001 Torr and 10 Torrs. In some implementations, the residual includes at least one of silicon atoms or a compound of silicon and oxygen.

In some implementations, the thermal treatment is performed to have the oxygen gas reacting with at least one of the silicon atoms or the compound of silicon and oxygen to form a gaseous compound of silicon and oxygen. In some implementations, the gaseous compound of silicon and oxygen is silicon monoxide. In some implementations, a selective epitaxial growth operation is performed to form a second layer on a bottom of the opening.

According to still another aspect of the present disclosure, a method for forming a three-dimensional (3D) memory device is disclosed. A stack structure is formed on a substrate. The stack structure includes a plurality of interleaved first stack layers and second stack layers. An opening is formed extending vertically through the dielectric stack. A thermal treatment is performed to transform a residual that residues in the opening when forming the opening to a gaseous compound. The residual includes at least one of silicon atoms or a compound of silicon and oxygen. A channel structure is formed in the opening.

In some implementations, at least an oxygen gas is provided to react with at least one of the silicon atoms or the compound of silicon and oxygen in the opening to form a gaseous compound of silicon and oxygen. In some implementations, the gaseous compound of silicon and oxygen is silicon monoxide.

In some implementations, the thermal treatment is performed at a treatment temperature between 800° C. and 1,300° C. In some implementations, the thermal treatment is performed within a treatment time of less than 10 minutes. In some implementations, at least an oxygen gas is provided to perform the thermal treatment, the oxygen gas having a partial pressure between 0.0001 Torr and 10 Torrs.

In some implementations, a post-etch treatment is performed to remove an oxide layer on a bottom surface of the opening. In some implementations, a shallow recess is performed by removing a part of the sacrificial layers abutting a sidewall of the opening. In some implementations, a selective epitaxial growth operation is performed to form a second layer is formed on a bottom of the opening.

According to a further aspect of the present disclosure, a semiconductor manufacturing device is disclosed. The semiconductor manufacturing device includes a reaction chamber, a substrate holder located in the reaction chamber to hold a substrate, and a heater in the reaction chamber to control a process temperature. The gas source includes at least oxygen gas. The process temperature in the reaction chamber is between 800° C. and 1,300° C. The reaction chamber is configured to perform a thermal treatment on the substrate to transform a residual on the substrate to a gaseous compound. The gaseous compound is a gaseous compound of silicon and oxygen.

In some implementations, the semiconductor manufacturing device further includes a controller for controlling a heater temperature of the heater between 800° C. and 1,300° C. and controlling the gas source to provide at least oxygen gas to the chamber, during the thermal treatment to constitute a chamber environment of the chamber capable of transforming the residual on the substrate to the gaseous compound.

In some implementations, the residual on the substrate includes at least one of silicon atoms or a compound of silicon and oxygen. In some implementations, the gaseous compound is silicon monoxide.

In some implementations, the reaction chamber is configured to perform the thermal treatment on the substrate within a treatment time less than 10 minutes. In some implementations, the oxygen gas has a partial pressure between 0.0001 Torr and 10 Torrs.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A method for forming a semiconductor structure, comprising:
forming a first layer on a substrate;
forming an opening extending vertically through the first layer; and
performing a thermal treatment to the opening to remove a residual that residues in the opening when forming the opening, comprising:
providing at least an oxygen gas to react with the residual in the opening to form a gaseous compound of silicon and oxygen.

2. The method of claim 1, after performing the thermal treatment to the opening to remove the residual that residues in the opening when forming the opening, further comprising:
forming a channel structure in the opening.

3. The method of claim 1, after performing the thermal treatment to the opening to remove the residual that residues in the opening when forming the opening, further comprising:
performing a selective epitaxial growth operation to form a second layer on a bottom of the opening.

4. The method of claim 1, wherein performing the thermal treatment to the opening to remove the residual that residues in the opening when forming the opening, comprises:
performing the thermal treatment at a treatment temperature between 800° C. and 1,300° C.

5. The method of claim 1, wherein performing the thermal treatment to the opening to remove the residual that residues in the opening when forming the opening, comprises:
performing the thermal treatment within a treatment time of less than 10 minutes.

6. The method of claim 1, wherein performing the thermal treatment to the opening to remove the residual that residues in the opening when forming the opening, comprises:
providing the oxygen gas having a partial pressure between 0.0001 Torr and 10 Torrs.

7. The method of claim 1, wherein the residual comprises at least one of silicon atoms or a compound of silicon and oxygen.

8. The method of claim 7, wherein providing at least the oxygen gas to react with the residual in the opening to form the gaseous compound of silicon and oxygen, comprises:
providing at least the oxygen gas to react with the at least one of the silicon atoms or the compound of silicon and oxygen to form the gaseous compound of silicon and oxygen.

9. The method of claim 8, wherein the gaseous compound of silicon and oxygen is silicon monoxide.

10. The method of claim 1, after forming the opening extending vertically through the first layer, further comprising:
performing a post-etch treatment to remove an oxide layer on a bottom surface of the opening.

11. The method of claim 1, the first layer includes a stack structure comprising a plurality of interleaved first stack layers and second stack layers.

12. A method for forming a semiconductor structure, comprising:
forming a first layer on a substrate;
performing an etch operation to form an opening extending vertically through the first layer; and
performing a thermal treatment to the opening to remove a residual that residues in the opening when forming the opening, comprising:
providing at least an oxygen gas to react with the residual at a treatment temperature between 800° C. and 1,300° C.

13. The method of claim 12, wherein performing the thermal treatment to the opening to remove the residual that residues in the opening when forming the opening, further comprises:
performing the thermal treatment within a treatment time of less than 10 minutes.

14. The method of claim 12, wherein providing at least the oxygen gas to react with the residual, comprises:
providing the oxygen gas having a partial pressure between 0.0001 Torr and 10 Torrs.

15. The method of claim 12, wherein the residual comprises at least one of silicon atoms or a compound of silicon and oxygen.

16. The method of claim 15, wherein performing the thermal treatment to the opening to remove the residual in the opening, comprises:
performing the thermal treatment to have the oxygen gas reacting with the at least one of the silicon atoms or the compound of silicon and oxygen to form a gaseous compound of silicon and oxygen.

17. The method of claim 16, wherein the gaseous compound of silicon and oxygen is silicon monoxide.

18. The method of claim 12, after performing the thermal treatment to the opening to remove the residual in the opening, further comprising:
performing a selective epitaxial growth operation to form a second layer on a bottom of the opening.

19. A method for forming a three-dimensional (3D) memory device, comprising:
forming a stack structure on a substrate, the stack structure comprising a plurality of interleaved first stack layers and second stack layers;
forming an opening extending vertically through the stack structure;
performing a thermal treatment to transform a residual that residues in the opening when forming the opening to a gaseous compound, wherein the residual comprises at least one of silicon atoms or a compound of silicon and oxygen; and
forming a channel structure in the opening.

20. The method of claim 19, wherein performing the thermal treatment to transform the residual that residues in the opening when forming the opening to the gaseous compound, comprises:
providing at least an oxygen gas to react with the at least one of the silicon atoms or the compound of silicon and oxygen in the opening to form a gaseous compound of silicon and oxygen.
